(19) United States
(12) Patent Application Publication
(10) Pub. No.: US 2009/0039880 A1
(43) Pub. Date: Feb. 12, 2009

(54) Electric current detector having detector element holder coupled to magnetic core casing

(75) Inventors: Kousuke Nomura, Okazaki-city (JP); Seiichirou Otake, Hazu-gun (JP); Takeshi Tsukamoto, Okazaki-city (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 12/222,194

(22) Filed: Aug. 5, 2008

(30) Foreign Application Priority Data
Aug. 7, 2007 (JP) 2007-205872

(51) Int. Cl. G01R 33/02

(52) U.S. Cl. 324/252

(57) ABSTRACT

An electric current detector according to the present invention detects an amount of current flowing through a conductor inserted into a through-hole of the current detector. The current detector includes a magnetic core casing in which a ring-shaped magnetic core having an air gap is molded and a detector element holder made by resin on which a detector element such as a Hall element is mounted. The detector element holder is coupled to the magnetic core casing so that the detector element is correctly positioned in the air gap of the ring-shaped magnetic core. Since the detector element is exposed to the air gap without being molded by resin, the detection accuracy is not affected by temperature changes in the course of usage. The detector element holder is simply coupled to the magnetic core casing without using complex connecting members. Accordingly, the electric current detector is manufactured at a low cost.

### CROSS-REFERENCE TO RELATED APPLICATION

This application is based upon and claims benefit of priority of Japanese Patent Application No. 2007-205872 filed on Aug. 7, 2007, the content of which is incorporated herein by reference.

### BACKGROUND OF THE INVENTION

1. Field of the Invention

The present invention relates to an electric current detector (or ammeter) having a detector element holder coupled to a magnetic core casing.

2. Description of Related Art

An example of an electric current detector that includes a detector element disposed in an air gap of a magnetic circuit is disclosed in JP-A-2006-78255. A relevant portion of the electric current detector 80 is shown in FIG. 6 attached hereto. A Hall element 83 mounted on a base plate 89 is positioned in an air gap 81 of a magnetic core 82. A bus-bar 87 inserted into a center through-hole 86 of a holder is positioned in an inner space 85 of a casing 84. The magnetic core 82, the Hall element 83 and the bus bar 87 are disposed in the inner space 85 of the casing 84 and integrally molded with a molding material. A connector 88 connected to the bus-bar 87 is led out of the casing 84. Current supplied from the connector 88 to the bus-bar is detected by the Hall element 83.

Another example of an electric current detector 90 is disclosed in JP-A-2006-519375. A relevant portion of the detector 90 is shown in FIG. 7 attached hereto. The detector 90 includes a cover 92, a magnetic circuit 93, a detector 94, an outer casing 91 and connector terminals 95. The magnetic circuit 93 in a circular shape is mounted in the outer casing 91 with a bracket 97. The detector 94 includes a detector cell 98 positioned in an air gap 96 of the magnetic circuit 93. The outer casing 91 and the cover 92 have a center through-hole 99 into which a conductor is disposed. Electric current supplied to the conductor disposed in the center through-hole 99 is detected by the detector cell 98 connected to the connecting terminals 95.

In the electric current detector 80 shown in FIG. 6, the Hall element 83 and the magnetic core 82 are disposed in the inner space 85 of the casing and molded together with other components by potting. Since components disposed in the inner space 85 are molded by potting, these components are protected from water. For this reason, a number of the current detectors are made by this method these days. However, a following problem is involved in this structure. Since the molding material holding the components in the inner space 85 expands or shrinks according to temperature, outputs of the Hall cell 83 deviate due to temperature changes. In addition, it is necessary to keep the molding material at a high temperature for about two hours for curing the molding material, making a manufacturing cost high.

In the electric current detector 90 shown in FIG. 7, the problem due to temperature changes is not involved because the components are not molded. However, the structure of the detector 90 is complex and the components are mounted on the casing in a complex manner. This makes the manufacturing cost of the detector 90 high.

### SUMMARY OF THE INVENTION

The present invention has been made in view of the above-mentioned problem, and an object of the present invention is to provide an improved electric current detector, in which detection accuracy is not affected by temperature changes and time lapsed in usage while suppressing a manufacturing cost.

The electric current detector according to the present invention is advantageously used in an automotive vehicle. The electric current detector is composed of a magnetic core casing and a detector element holder, both being connected to each other. A ring-shaped magnetic core having an air gap is molded with a molding resin, thereby forming the magnetic core casing. The air gap of the ring-shaped magnetic cover is positioned to face an opening of the casing. A through-hole for inserting a conductor, through which electric current to be detected flows, is formed in the casing.

A resin holder on which a current detector element such as a Hall element or a Hall IC is mounted is formed by resin molding. The resin holder also includes terminal pins electrically connected to the detector element that are insert-molded. The resin holder on which the detector element is mounted is coupled to the magnetic core casing so that the detector element is correctly positioned in the air gap of the ring-shaped magnetic core. The opening of the casing is closed with the resin holder by coupling the resin holder to the casing. A flange of the holder is connected to an inner bore of casing with adhesive or laser welding. An amount of current flowing through the conductor inserted into the through-hole of the casing is detected by the detector element, and electrical signals representing the detected results are outputted through the terminal pins.

In order to correctly position the detector element in the air gap, it is preferable to form depressions and projections engaging each other on the magnetic core casing and the detector element holder. Alternatively, tapered surfaces contacting closely each other may be formed on both of the casing and the holder. Two or more detector elements, one having a high sensitivity for measuring a small amount of current and the other having a low sensitivity for measuring a large amount of current, may be mounted on the resin holder. A temperature-sensor element may be mounted on the resin holder together with the current detector element.

Since the detector element is exposed in the air gap of the ring-shaped magnetic core without being molded by potting, detection accuracy of the current is not affected by temperature changes in the course of usage. Since the detector element holder is connected to the magnetic core casing by simply coupling both, the electric current detector can be manufactured at a low cost according to the present invention. Other objects and features of the present invention will become more readily apparent from a better understanding of the preferred embodiment described below with reference to the following drawings.

### BRIEF DESCRIPTION OF THE DRAWINGS

FIG. 1 is a transparent perspective view showing an electric current detector according to the present invention;

FIG. 2A is a cross-sectional view showing a magnetic core casing formed by molding;

FIG. 2B is a cross-sectional view showing a detector element holder to be coupled to the magnetic core casing shown in FIG. 2A;

FIG. 2C is a cross-sectional view showing the electric current detector composed of the magnetic core casing and the detector element holder;

FIG. 3A is a plan view showing a modified form of the detector element holder;

FIG. 3B is a plan view showing another modified form of the detector element holder;

FIG. 4A is a cross-sectional view showing a resin casing having projections for correctly positioning the detector element holder;

FIG. 4B is a cross-sectional view showing a detector element holder having depressions for correctly coupling it to the resin casing;

FIG. 5A is a cross-sectional view showing a resin casing having a tapered surface for correctly coupling a detector element holder to the resin casing;

FIG. 5B is a plan view showing a detector element holder having a tapered surface to be coupled to the tapered surface of the resin casing shown in FIG. 5A;

FIG. 6 is a perspective view showing a conventional electric current detector disclosed in JP-A-2006-78255; and

FIG. 7 is an exploded perspective view showing another conventional electric current detector disclosed in JP-A-2006-519375.

### DETAILED DESCRIPTION OF THE PREFERRED EMBODIMENT

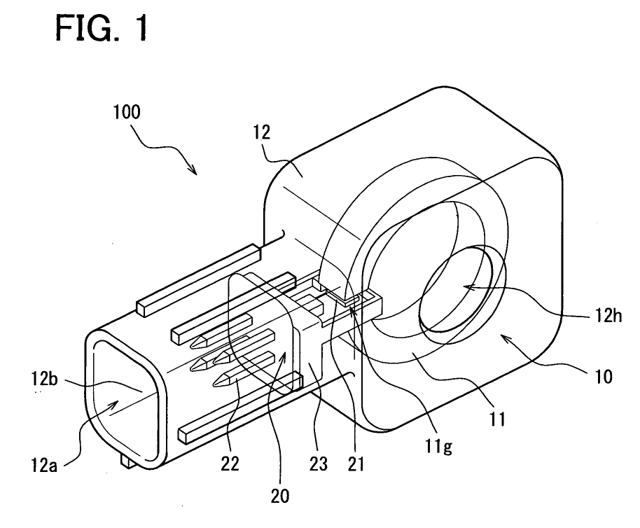

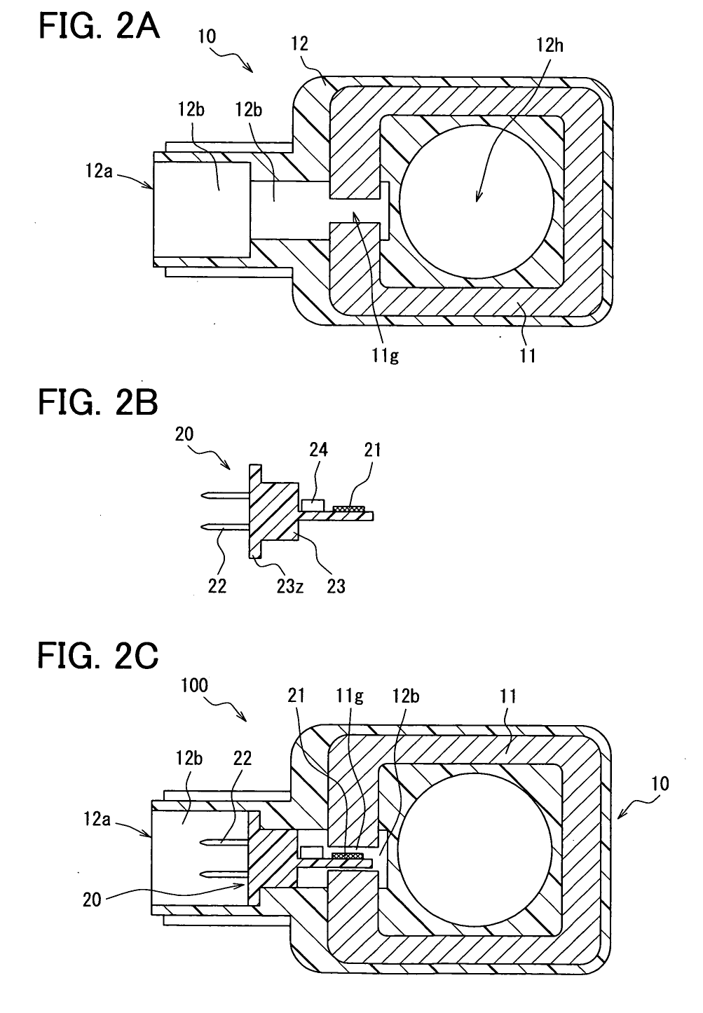

A preferred embodiment of the present invention will be described with reference to accompanying drawings. As shown in FIGS. 1 and 2C, an electric current detector 100 is composed of a magnetic core casing 10 and a detector element holder 20. As shown in FIG. 2A, a ring-shaped magnetic core 11 having an air gap 11g is held in a resin casing 12 formed by molding, thereby forming the magnetic core casing 10. The resin casing 12 has an opening 12a at it one end and inner spaces 12b open to the opening 12a. The air gap 11g of the magnetic core 11 is open to the opening 12a via the inner spaces 12b. The magnetic core casing 10 has a center through-hole 12h for inserting a conductor such as a bus-bar through which electric current to be detected flows.

In the molding process for forming the magnetic core casing 10, the magnetic core 11 is held in a molding die as an insert with heated pins as described in JP-A-2003-127185. In this manner, the magnetic core 11 can be correctly positioned in the resin casing 12.

As shown in FIG. 2B, a detector element 21 (in a form of a bare chip) for converting magnetic field intensity to an electric voltage, such as a Hall element or a Hall IC, is mounted on a resin holder 23 made of resin by molding. Terminal pins 22 electrically connected to the detector element 21 are insert-molded in the resin holder 23. Electric components 24 such as a capacitor are also mounted on the resin holder 23. A flange 23z is formed on the resin holder 23. The resin holder 23, the detector element 21 and other components are collectively referred to as a detector element holder 20.

As shown in FIG. 2C, the detector element holder 20 is coupled to the magnetic core casing 10, so that the detector element 21 is correctly positioned in the air gap 11g. By coupling the detector element holder 20 to the magnetic core casing 10, the opening 12a is closed by the flange 23z, and an inner bore of the inner space 12b is closed by a body portion of the resin holder 23. Connection between the detector holder 20 and the magnetic core casing 10 may be made by adhesive or laser welding.

Advantages attained in the electric current detector 100 described above will be summarized below. The detector element 21 mounted on the resin holder 23 is exposed to the air gap 11g without being molded with a resin material as done in the conventional detector 80 shown in FIG. 6. Therefore, the thermal stress of the molding resin due to temperature changes is not imposed on the detector element 21. Accordingly, the outputs of the electric current detector 100 are less affected by temperature changes and are stable in a course of usage.

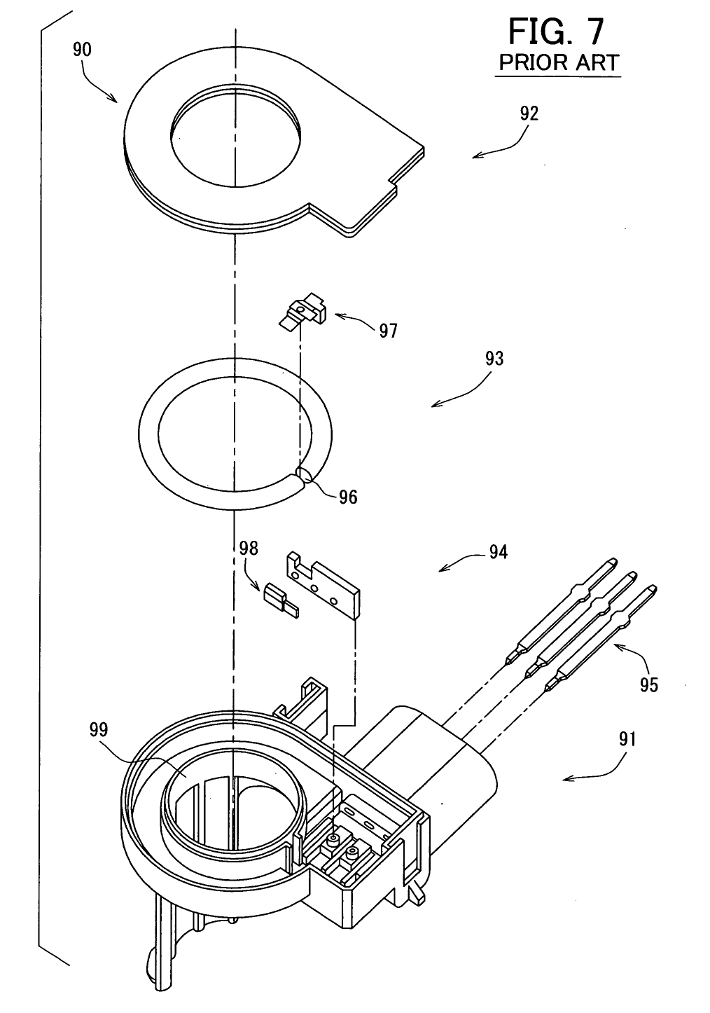

The magnetic core 11 is held in the resin casing 12 that is formed by molding. Therefore, no particular components for holding the magnetic core 11 in the resin casing 12 are necessary, as opposed to the structure of the conventional detector 90 shown in FIG. 7. In addition, the process for curing the potting resin, which is necessary for the conventional detector 80 shown in FIG. 6, is not necessary. Accordingly, the electric current detector 100 according to the present invention can be manufactured at a low cost. The electric current detector according to the present invention is advantageously used as a current detector mounted on an automotive vehicle, which is used under a severe environment and conditions.

It is preferable to position the terminal pins 22 within the inner space 12b of the resin casing 12, as shown in FIG. 2C. In this manner, the terminal pins 22 are protected from water. It is also preferable to connect the detector element holder 20 to the magnetic core casing 10 by applying adhesive or by laser-welding all around the flange 23z. Thus, the detector 100 is well protected against water.

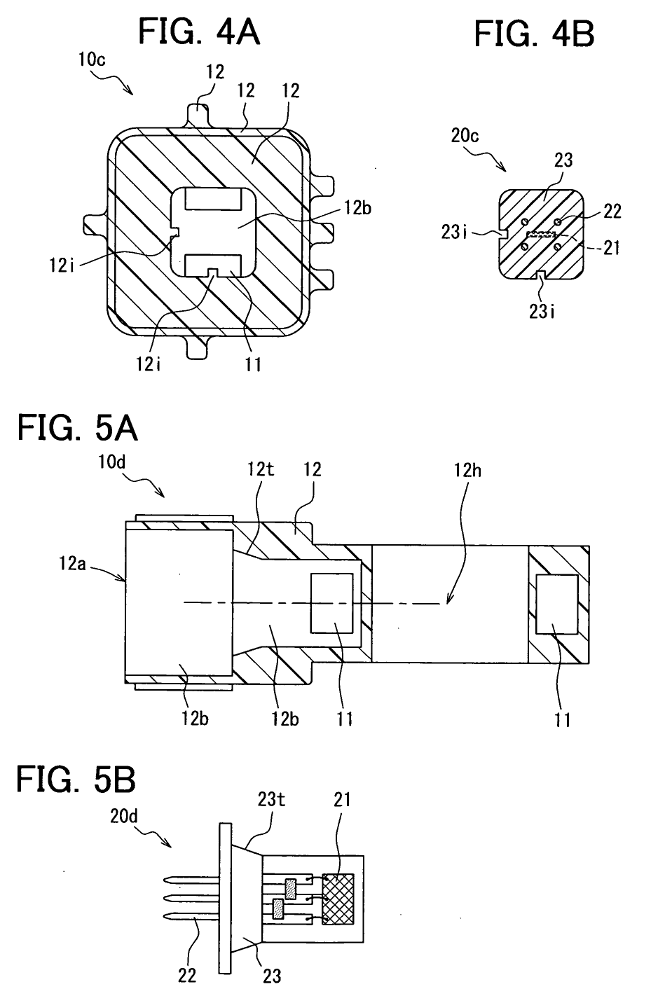

It is preferable to provide a structure for correctly positioning the detector element holder 20 relative to the magnetic core casing 10. An example of the correctly positioning structure is shown in FIGS. 4A and 4B. In this example, a projections 12i are formed on inner surfaces of the inner space 12b of the magnetic core casing 10c, and depressions 23i engaging with the projections 12i are formed on an outer periphery of the detector element holder 20c. This positioning structure may be modified by making projections on the detector element holder 20c and depressions on the magnetic core casing 10c.

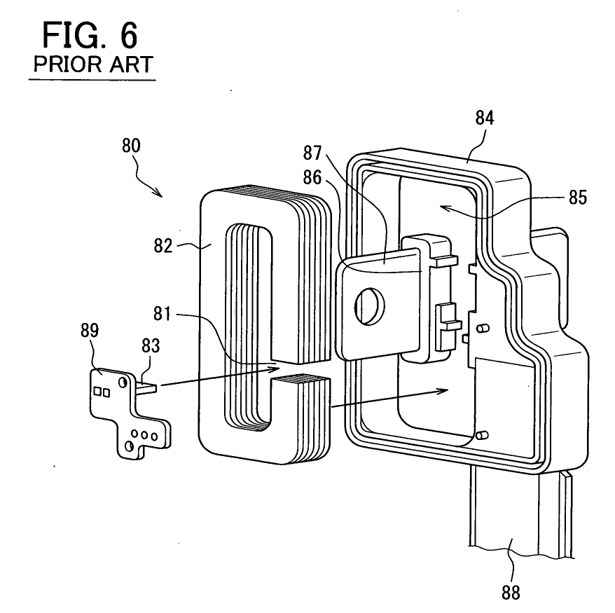

Another example of the correctly positioning structure is shown in FIGS. 5A and 5B. In this example, a tapered surface 12t is formed on an inner surface of the inner space 12b of the magnetic core casing 10d, and another tapered surface 23t is formed on the detector element holder 20d. By making a close contact between both tapered surfaces 12t, 23t, the detector element 21 mounted on the resin holder 23 is correctly positioned in the air gap 11g. The positioning structures exemplified above are easily formed without increasing the manufacturing cost.

The present invention is not limited to the embodiment described above, but it may be variously modified. For example, the detector element 21 mounted on the resin holder 23 is not limited to the Hall element or the Hall IC. Other detector elements for converting magnetic field intensity to electric voltage, such as a magneto-resistive element (MRE), may be used. Though it is preferable to mount the detector element 21 on the resin holder 23 in a form of a bare chip, it is possible to package the detector element with other electronic components.

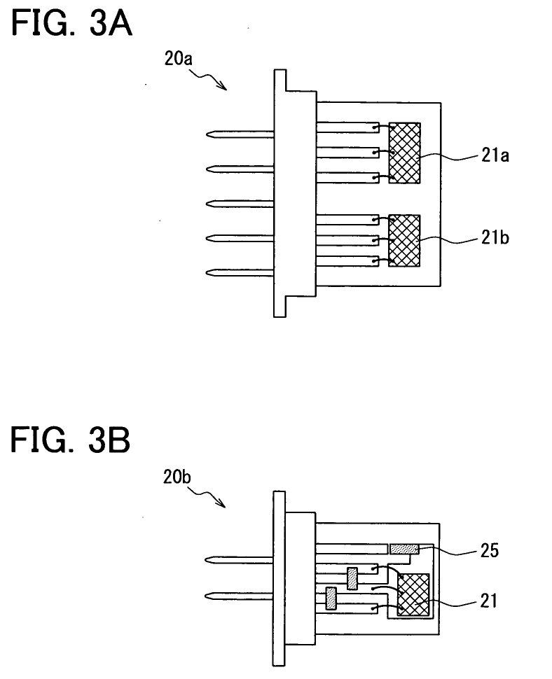

Plural detector elements 21 may be mounted on the resin holder 23. In an example shown in FIG. 3A, two detector elements 21a, 21b are mounted, forming the detector element holder 20a. In this case, it is possible to use one detector element 21a having a high sensitivity, which is able to detect a small amount of current around zero ampere, and to use another detector element 21b having a low sensitivity, which is able to detect a large amount of current. Thus, a wide range of current can be detected. Three or more detector elements may be mounted on the resin holder 23. As shown in FIG. 3B, a temperature sensor such as a thermistor 25 may be used in addition to the current detector element 21. In this manner, temperature can be detected together with current.

While the present invention has been shown and described with reference to the foregoing preferred embodiment and modified forms, it will be apparent to those skilled in the art that changes in form and detail may be made therein without departing from the scope of the invention as defined in the appended claims.

What is claimed is:

1. An electric current detector comprising:
a magnetic core casing made of resin having a ring-shaped magnetic core molded therein, the ring-shaped magnetic core including an air gap open to an opening to the magnetic core casing; and
a detector element holder made of resin holding a detector element for detecting electric current induced by a magnetic field, the detector element holder being fixedly connected to the opening of the magnetic core casing so that the detector element is positioned in the air gap of the magnetic core.

2. The electric current detector as in claim 1, wherein terminal pins electrically connected to the detector element are molded in the detector element holder so that the terminal pins are positioned within an inner space of the magnetic core casing.

3. The electric current detector as in claim 2, wherein means for correctly positioning the detector element holder relative to the magnetic core casing is formed on both the magnetic core casing and the detector element holder.

4. The electric current detector as in claim 3, wherein the correctly positioning means is composed of projections formed on the magnetic core casing and depressions formed on the detector element holder, the projections and depressions being formed to engage with each other.

5. The electric current detector as in claim 3, wherein the correctly positioning means is composed of tapered surfaces formed on the detector element holder and on the magnetic core casing, the tapered surfaces being formed to closely contact each other.

6. The electric current detector as in claim 1, wherein the magnetic core casing and the detector element holder are connected to each other by laser welding.

7. The electric current detector as in claim 1, wherein he detector element is a Hall IC.

8. The electric current detector as in claim 1, wherein a plurality of the detector elements are held on the detector element holder.

9. The electric current detector as in claim 1, wherein a temperature-detecting element is held on the detector element holder together with the detector element.

10. The electric current detector as in claim 1, wherein the electric current detector is a detector for use in an automotive vehicle.

11. The electric current detector as in claim 3, wherein the correctly positioning means is composed of projections formed on the detector element holder and depressions formed on the magnetic core casing, the projections and depressions being formed to engage with each other.
